(19) United States
(12) Patent Application Publication
(10) Pub. No.: US 2009/0153373 A1
(43) Pub. Date: Jun. 18, 2009

(54) KEY MODULE FOR ELECTRONIC DEVICES

(75) Inventor: TIEN-HUNG LIN, Tu-Cheng (TW)

Correspondence Address: PCE INDUSTRY, INC.;ATT. Steven Reiss, 458 E. LAMBERT ROAD, FULLERTON, CA, 92835, US

(73) Assignee: CHI MEI COMMUNICATION SYSTEMS, INC., Tu-Cheng City (TW)

(21) Appl. No.: 12/170,531

(22) Filed: Jul. 10, 2008

(30) Foreign Application Priority Data
Dec. 14, 2007 (CN) 200710203069.4

(51) Int. Cl. H03K 17/94

(52) U.S. Cl. 341/22

(57) ABSTRACT

A key module (10) includes a light guiding board (14), a flexible key board (12) disposed on the light guiding board, and a plurality of metallic elastic sheets (164). Each of the metallic elastic sheets is disposed on the light guiding board and located opposite to the flexible key board. The light guiding board deforms when the flexible key board is pressed thereby causing the metallic elastic sheet corresponding to a location of the flexible key board being pressed to be deformed.

### BACKGROUND OF THE INVENTION

1. Field of the Invention

The present invention relates to a key module for electronic devices.

2. Discussion of the Related Art

FIG. 1 shows a typical key module 10 including a flexible key board 12, a light guiding board 14 and a flexible-thin film 16. The light guiding board 14 is between the flexible key board 12 and the 16. The flexible key board 12, the light guiding board 14 and the flexible-thin film 16 are joined together by a binder. A surface 122 of the flexible key board 12 facing toward the light guiding board 14 includes a plurality of spaced-apart keys 124. A surface 142 of the light guiding board 14 facing the flexible-thin film 16 includes a plurality of signal projections 144 corresponding to the keys 124. A surface 162 of the flexible-thin film 16, which faces the opposite direction to the light guiding board 14, includes a plurality of metallic sheets 164 corresponding to the signal projections 144 of the light guiding board 14. When applying the key module 10 into electronic devices, such as cellular phone or portable digital assistant (PDA), the flexible-thin film 16 is arranged on circuit boards of the electronic devices, and the metallic sheets 164 are configured to correspond with switches on the circuit boards.

In view of the above, the typical key module 10 is manufactured by joining the flexible key board 12, the light guiding board 14 and the flexible-thin film 16 with metallic sheets 164 arranged thereon, and then attaching the flexible-thin film 16 on circuit boards of electronic devices. However, the thickness of the flexible thin film 16 increases the overall thickness of electronic devices. As a result, such key module is unable to satisfy the demand being light and thin for electronic devices.

Therefore, there is room for improvement within the art.

### BRIEF DESCRIPTION OF THE DRAWINGS

FIG. 1 is a schematic view of a typical key module; and

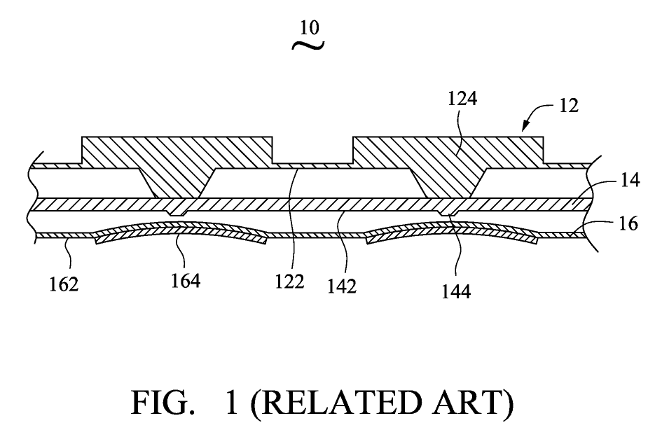

FIG. 2 is a schematic view of an exemplary embodiment of the present key module.

### DETAILED DESCRIPTION OF THE EMBODIMENTS

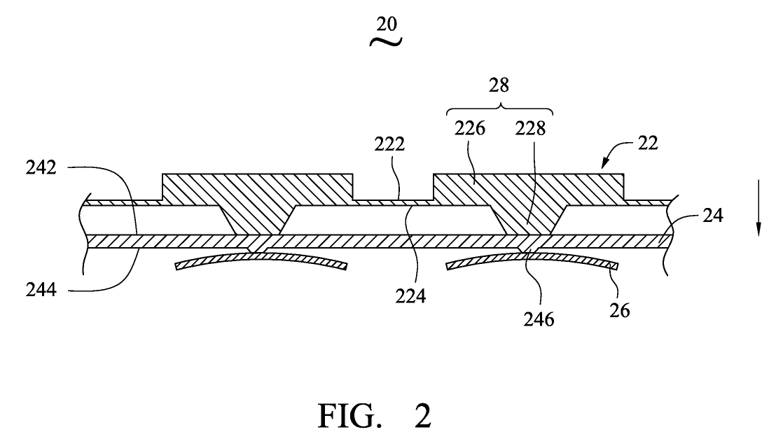

FIG. 2 shows an exemplary embodiment of the present key module 20. The key module 20 includes a flexible key board 22, a light guiding board 24 and metallic elastic sheets 26. The light guiding board 24 is disposed between the flexible key board 22 and metallic elastic sheets 26.

The flexible key board 22 includes a first surface 222 and an opposite second surface 224. The first surface 222 is the surface contacted by the user and the second surface 224 faces the light guiding board 24.

The flexible keyboard 22 includes a plurality of keycaps 28 for users to press. Each keycap 28 is formed by a first projection 226 and a second projection 228. The first projections 226 are formed on the first surface 222. The second projections 228 are formed on the second surface 224 and correspond to the first projections 226. In the exemplary embodiment, the first projections 226 are rectangular and the second projections 228 are trapezoidal. In alternative embodiments, the first projections 226 and the second projections 228 may have different shapes.

The light guiding board 24 includes a first surface 242 and an opposite second surface 244. The first surface 242 contacts the flexible key board 22 and the second surface 244 contacts the metallic elastic sheets 26. Each metallic elastic sheet 26 contacts the second surface 244 at locations corresponding to the locations of the second projections 228. In addition, a plurality of signal projections 246 are arranged to correspond to the second projections 228. In the exemplary embodiment, the signal projections 246 are trapezoidal. In alternative embodiments, the signal projections 246 may have different shapes.

The light guiding board 24 and the flexible key board 22 may be joined by binders, dual-sided adhesive tapes or integral binding. The light guiding board 24 may be made from one or several kinds of materials selected from the group of thermoplastic polyurethane elastomer, polycarbonate, polymethylate methacrylat and polyethylene terephthalate.

The metallic elastic sheets 26 are made of conductive metal, such as stainless steel or copper, and are elastic. The metallic elastic sheets 26 are respectively attached to the corresponding signal projections 246 by binding methods, such as pasting. It is not necessary to have signal projections 246. The metallic elastic sheets 26 may be directly attached to the second surface 244.

The light guiding board 24 is arranged on circuit boards of electronic devices, and the metallic elastic sheets 26 is arranged to correspond to switches on the circuit boards, which electrically connect or disconnect the key module 20 to the circuit boards of the electronic devices.

The first projections 226 of the flexible key board 22 can be pressed in the direction of the arrow shown in FIG. 2. As such, the corresponding second projections 228 is pressed in the same direction, thereby deforming the light guiding board 24. As a result, the switches on the circuit boards can be turned on or off. When one of the first projections 226 is pressed, the metallic elastic sheets 26 corresponding to the pressed first projection 226 deforms in the direction of the arrow shown in FIG. 2.

The present key module 20 allows the light guiding board 24 to be attached to the metallic elastic sheets 26 to reduce the overall thickness of the key module 20. In addition, without the need for the flexible-thin film, the manufacturing process of the key module 20 is simpler and more efficient.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A key module, comprising:
a light guiding board having first and second opposite surfaces;
a flexible key board attached to a first surface of the light guiding board;
a plurality of metallic elastic sheets, each of the metallic elastic sheets attached to a second surface of the light guiding board and located opposite to the flexible key board; and
wherein the light guiding board deforms when the flexible key board is pressed, thereby a portion of the metallic elastic sheet corresponding to the location of the flexible key board being pressed also deforms.

2. The key module of claim 1, wherein the flexible key board comprises a first surface having a plurality of first projections and an opposite second surface having a plurality of second projections corresponding to the first projections.

3. The key module of claim 2, wherein each of the first projections and the corresponding second knob form a keycap.

4. The key module of claim 3, wherein each of the metallic elastic sheets attaches to a location of the second surface of the light guiding board at a position corresponding to a keycap.

5. The key module of claim 2, wherein a plurality of signal projections are arranged on locations of the second surface that correspond to the second projections.

6. The key module of claim 5, wherein each metallic elastic sheet attaches to one of the signal projections.

7. The key module of claim 1, wherein the light guiding board and the flexible key board may be joined by binders, dual-sided adhesive tapes or integrally binding.
